(19) United States
(12) Patent Application Publication
(10) Pub. No.: US 2006/0170114 A1
(43) Pub. Date: Aug. 3, 2006

(54) Novel method for copper wafer wire bonding

(76) Inventors: Chao-Yuan Su, Koahsiung City (TW); Chen-Der Huang, Hsin-Chu (TW); Chien-Hsiun Lee, Hsin-Chu (TW); Hsin-Hui Lee, Kaohsiung (TW)

Correspondence Address: SLATER & MATSIL, L.L.P., 17950 PRESTON ROAD, SUITE 1000, DALLAS, TX, 75252, US

(21) Appl. No.: 11/047,060

(22) Filed: Jan. 31, 2005

(51) Int. Cl. H01L 23/52

(52) U.S. Cl. 257/784

(57) ABSTRACT

A method of bonding a conductive wire on copper pad is presented. A passivation layer is formed on a copper pad. The passivation layer has an opening through which at least a portion of the copper pad is exposed. A nickel-copper-phosphorous (Ni—Cu—P) layer is formed on the copper pad by electroless plating. A conductive wire is bonded through the Ni—Cu—P layer and to the copper pad. The Ni—Cu—P layer protects the underline copper pads from oxidation so that a better bonding can be formed between the conductive wire and the copper pad.

### TECHNICAL FIELD

This invention relates generally to semiconductor chip packaging and in particular to bonding pads coated with nickel-copper-phosphorous alloy.

### BACKGROUND

The art of making an electrical connection to a semiconductor chip by wire bonding from a bonding pad on the chip to a corresponding pad or lead on a chip carrier is widely known and practiced in the semiconductor industry. It is a common practice to bond using gold (Au) wire to copper (Cu) pads. Gold has good conductivity so that it is widely used as the bonding wire. It also has good adhesion to the copper pads. However, a copper pad has an undesired characteristic, it oxidizes readily at slightly elevated temperatures (about 40° C.), and the oxide continues to grow in thickness. The copper oxide on the surface of the copper pad prevents the underneath copper from forming a good bond to gold wire.

Various methods have been practiced to avoid this problem. The copper oxide on the surface of the copper pad can be cleaned with the aid of plasma. The wafer must be bonded within about 15 minutes of the cleaning, otherwise the oxidation reoccurs. Therefore, it is hard to use plasma cleaning in mass production.

It is also a known practice to sputter an aluminum film on the surface of the copper pad. Aluminum is harder to oxidize. When it oxidizes, a thin layer of dense oxide isolates the underneath layer of aluminum from oxygen so that the thickness does not increase with time. This method is good for mass production. One drawback is that extra process steps, (such as photolithography, etching etc.), are involved to form an appropriate aluminum layer on the surface of copper pads, therefore, production cost is higher.

Yet another method was developed to plate a nickel (Ni) layer on the surface of a copper pad to prevent oxidation by using electroless nickel plating. Electroless plating has unique physicochemical and mechanical properties for which they are being used increasingly for the plating on metals. Electroless plating is performed by the controlled chemical reduction of ions onto a catalytic surface, the plating itself is catalytic to the reduction reaction and the reaction continues as long as the surface remains in contact with the plating solution until the solution gets depleted of solute ions. The coating is uniform throughout the plating surface since no electric current is used. Therefore, all parts of the copper area are deposited with substantially equal thickness. This process offers distinct advantages when plating irregularly shaped objects, holes, and recesses. Among the advantageous properties, uniformity, solderability, and high hardness are common properties sought.

However, the Ni layer pad has high stress and inferior adhesion to the copper, when gold wire is bonded, the Ni layer cracks and peels from the copper pad and the bonding fails. An improvement was made to plate a thin layer of nickel followed by a thicker layer of gold prior to bonding a gold wire. The nickel layer provides a diffusion barrier to prevent the formation of copper-gold intermetallic alloys between the copper pad and the gold layer. The gold layer then provides a surface for making conventional wire bond connections. A fairly thick layer of gold, typically greater than fourteen micro-inches is needed for satisfactory bonds with gold wire of 0.8 to 1.5 milli-inch diameter, and the production cost is increased.

What is needed, therefore, is a low cost, less process step method for bonding wire on copper pads.

### SUMMARY OF THE INVENTION

The preferred embodiment of the present invention presents a method of wire bonding to a copper pad.

In accordance with one aspect of the present invention, a passivation layer is formed over or around a copper pad. The passivation layer has an opening through which at least a portion of the copper pad is exposed. A nickel-copper-phosphorous (Ni—Cu—P) alloy layer is formed on the copper pad by electroless plating. A gold wire is bonded through the Ni—Cu—P layer and to the copper pad. The Ni—Cu—P layer protects the underneath copper pads from oxidation so that a better bonding can be formed between the gold wire and the copper pad.

The preferred embodiment of the present invention has various advantage features. There is no need to have extra plating masks since the existing passivation layer is used as the plating mask. There is also no need to have extra photo and etching process. Mass production can be achieved base on the preferred embodiment of the present invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 and FIG. 1a illustrate copper pads masked by a passivation layer;

FIG. 2 illustrates a Ni—Cu—P alloy layer formed on copper pads; and

FIG. 3 illustrates a gold wire bonded to the copper pad by a wire-bonding tool.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the preferred embodiment of the present invention, a thin layer of nickel-copper-phosphorous (Ni—Cu—P) alloy is deposited on the surface of a copper pad by electroless plating. The thin layer of Ni—Cu—P alloy prevents the copper from oxidation, and therefore improves the bonding between a gold wire and the copper pad. The Ni—Cu—P alloy layer is inactive and it does not oxidize in a way affecting bonding.

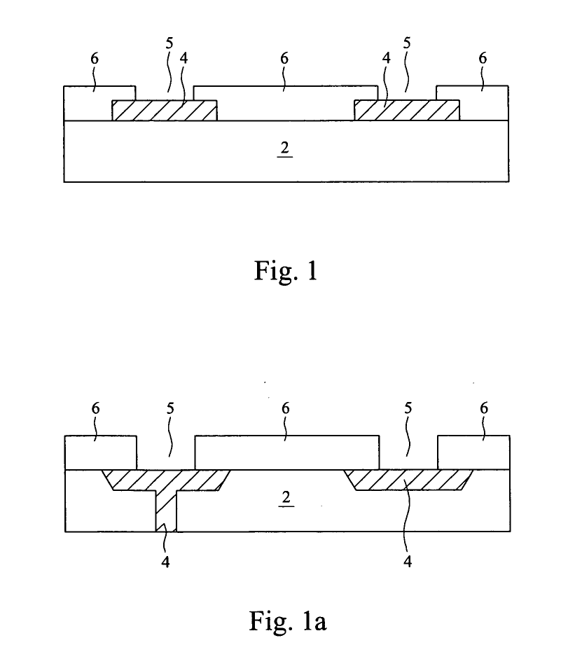

FIGS. 1 through 3 illustrate a preferred embodiment of the present invention. As shown in FIG. 1, copper pads 4 is formed on a base material 2. Base material 2 can be a semiconductor, a metal or any other material formed in a wafer. A passivation layer 6 is formed with an opening 5 to expose the copper pad 4. In one embodiment, the passivation layer 6 is silicon nitride deposited by low-pressure chemical vapor deposition (LPCVD) or plasma enhanced CVD (PECVD). Copper pads 4 can also be formed in the based material 2 using damascene processes, as illustrated in FIG. 1a.

A Ni—Cu—P alloy layer 8 is selectively deposited on the copper pad 4, as illustrated in FIG. 2, by using electroless alloy plating. A source of Ni ions, typically nickel sulphate or nickel chloride is used. The phosphorous ions are provided by hypophosphite, which is also used as a reducing agent in the solution.

A reducing agent is needed to supply electrons for the reduction of nickel and copper. When the reducing agent reacts with the Ni ions, following reaction occurs:
Ni²⁺+2e->Ni [Eq. 1]
Cu²⁺+2e->Cu [Eq. 2]
Ni and Cu ions are reduced and deposited on the surface of the copper pad 4.

In the preferred embodiment, hypophosphite and Dimethylamine Borane (DMAB) are used as the reducing agents. Catalytic oxidation of the hypophosphite yields electrons at the catalytic surface and not only provides the electrons needed by the reduction reaction, but hypophosphite also supplies phosphorous to the Ni—Cu—P alloy.

The DMAB is an effective reducing agent. A significant advantage of using DMAB as a reducing agent is the selective deposition on the copper surface. During the course of the deposition, Ni—Cu—P alloy is deposited on the surface of copper pad 4 and continues to grow. There is substantially no Ni—Cu—P alloy deposited on the surface of the passivation layer 6. Therefore, there is no extra mask required to mask the passivation layer 6 as the passivation layer 6 acts as the mask for itself. Compared to the prior art that aluminum is deposited, the preferred embodiment reduces the processing steps and masks thereby reduces the production cost.

Another advantage of using DMAB is that it works as a reducing agent over a wide range of pH. As known in the art, the solution's operating pH is an important parameter because it affects the plating rate and the amount of phosphorus co-deposited. Higher pH values favor lower phosphorus contents in the deposit while increasing the plating rate.

Cu and P in the Ni—Cu—P alloy 8 helps reduce the stress generated in the Ni—Cu—P alloy layer 8 due to the characteristic mismatch between copper pad 4 and the Ni—Cu—P layer 8. With a lower stress, the Ni—Cu—P alloy 8 has better adhesion to the copper pad 4. When the gold wire is bonded to the copper pad 4, the Ni—Cu—P layer 8 does not crack and peel from the copper pad 4 and better results can be achieved. The stress value is affected by various factors such as the area of the copper pad, the thickness of the Ni—Cu—P alloy, etc.

It is desired that in the Ni—Cu—P alloy, the weight percentage of Ni is about 96% to about 97%. The weight percentage of Cu is preferably between about 2 to about 4, more preferably about 2.5 to about 3. The weight percentage of P in the Ni—Cu—P alloy is preferably less than about 0.5%, more preferably between about 0.3 to about 0.4.

The deposition rate is affected by temperature and is low at a lower temperature, and increases when the temperature increases. The deposition rate is also affected by the pH value of the plating solution. However, the deposition rate only affects the thickness and how much time it takes to deposit, it has no significant affect to the ability of preventing copper from oxidation unless the Ni—Cu—P alloy 8 is too porous that oxygen can penetrate through it.

To maintain the proper metal to reducing agent ratio, the solution should be periodically analyzed and adjusted. The reducing agents are consumed so that the plating process is affected. During plating, the reducing agent is consumed in a given ratio to the nickel and copper during plating. While the concentration of DMAB and hypophosphite can always be tested, the appropriate amount of hypophosphite can be adjusted by observing the plating condition during the course of reaction. Typically, weak hydrogen evolution is an indication of a low concentration of hypophosphite and a vigorous hydrogen evolution indicates excess hypophosphite. In the preferred embodiment, since the thickness of the Ni—Cu—P layer is only about 1 μm to about 2 μm, it is expected that the concentrations of the solution do not change significantly during the course of one plating process. However, if multiple platings are performed, the solution needs to be adjusted.

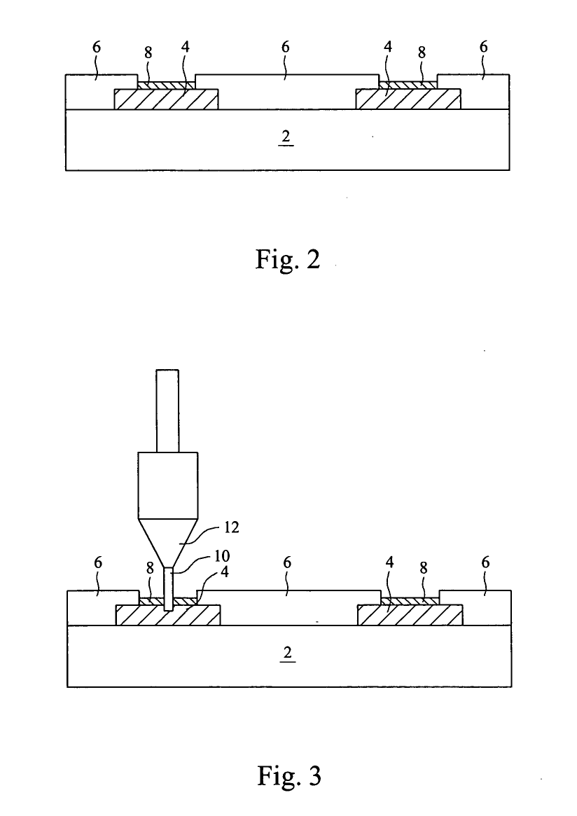

FIG. 3 illustrates a conductive wire 10 bonded to the copper pad 4. Device 12 is a wire-bonding tool. In the preferred embodiment, the conductive wire 10 comprises gold since gold has good conductivity and good bondability to copper. It is to be noted that the gold wire penetrates the Ni—Cu—P alloy layer 8 and is bonded to the copper pad 4. As has been explained, the copper pad 4 is protected by the thin Ni—Cu—P alloy 8 from oxidation, therefore better bonding can be achieved. The Ni—Cu—P alloy layer 8 has a thickness of about 1 μm to about 2 μm. The bonding tool needs to be adjusted so that the conductive wire 10 goes through the Ni—Cu—P alloy layer 8 without damaging the copper pad 4.

The preferred embodiment of the present has following advantageous features. First, there is no extra plating mask needed. By using the existing passivation layer as a mask and selecting proper reducing agents, the Ni—Cu—P alloy is plated to the copper pads only. Also, there is no extra photo and etching processes so that the production cost is reduced. Second, the present embodiment is suitable for mass production.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of bonding a metal wire on copper pad comprising the steps of:
forming a passivation layer over a copper pad wherein the passivation layer has an opening and at least a portion of the copper pad is exposed;
forming a nickel-copper-phosphorous (Ni—Cu—P) alloy layer selectively over the copper pad; and
bonding a conductive wire through the Ni—Cu—P alloy layer and to the copper pad.

2. The method of claim 1 wherein the step of forming the Ni—Cu—P alloy layer comprises performing an electroless plating over the copper pad.

3. The method of claim 2 wherein the electroless plating is performed in a plating solution comprising hypophosphite and dimethylamine borane (DMAB).

4. The method of claim 1 wherein the Ni—Cu—P alloy layer has a thickness of between about 1 μm and about 2 μm.

5. The method of claim 1 wherein the Ni—Cu—P alloy layer contains less than about 0.5 weight percent phosphorous.

6. The method of claim 1 wherein the Ni—Cu—P alloy layer contains between about 0.3 and about 0.4 weight percent phosphorous.

7. The method of claim 1 wherein the Ni—Cu—P alloy layer contains between about 2 and about 4 weight percent copper.

8. The method of claim 1 wherein the Ni—Cu—P alloy layer contains between about 2.5 and about 3 weight percent copper.

9. The method of claim 1 wherein the Ni—Cu—P layer contains between about 96 and about 97 weight percent nickel.

10. The method of claim 1 wherein the conductive wire comprises gold.

11. A method of bonding a metal wire on copper pad comprising the steps of:
forming a passivation layer over a copper pad wherein the passivation layer has an opening and at least a portion of the copper pad is exposed;
forming a nickel-copper-phosphorous (Ni—Cu—P) alloy layer selectively over the copper pad, wherein the Ni—Cu—P alloy layer comprises less than about 0.5 weight percent phosphorous, about 2 to about 4 weight percent copper, and about 96 to about 97 weight percent nickel; and
bonding a conductive wire through the Ni—Cu—P alloy layer and to the copper pad.

12. A wire bonding structure comprising:
a passivation layer over a copper pad wherein the passivation layer has an opening exposing at least a portion of the copper pad;
a Nickel-Copper-Phosphorous (Ni—Cu—P) layer over the copper pad and in the opening; and
a conductive wire bonded through the Ni—Cu—P layer and to the copper pad.

13. The wire bonding structure of claim 12 wherein the Ni—Cu—P alloy layer has a thickness of between about 1 μm and about 2 μm.

14. The wire bonding structure of claim 12 wherein the Ni—Cu—P alloy layer contains less than about 0.5 weight percent phosphorous.

15. The wire bonding structure of claim 12 wherein the Ni—Cu—P alloy layer contains between about 0.3 and about 0.4 weight percent phosphorous.

16. The wire bonding structure of claim 12 wherein the Ni—Cu—P alloy layer contains between about 2 and about 4 weight percent copper.

17. The wire bonding structure of claim 12 wherein the Ni—Cu—P alloy layer contains between about 2.5 and about 3 weight percent copper.

18. The wire bonding structure of claim 12 wherein the Ni—Cu—P alloy layer contains between about 96 and about 97 weight percent nickel.

19. The wire bonding structure of claim 12 wherein the conductive wire comprises gold.
